(19) United States
(12) Patent Application Publication
(10) Pub. No.: US 2026/0341644 A1
(43) Pub. Date: Oct. 29, 2026

(54) PLASMA-EXPOSED PARTS COMPRISING AN ETCH-RESISTANT MATERIAL

(71) Applicant: Lam Research Corporation, Fremont, CA (US)

(72) Inventors: Mansa RAJAGOPALAN, Fremont, CA (US); Kyle Brandon TOM, San Jose, CA (US); Aditi KHIRBAT, Fremont, CA (US); Justin Charles CANNIFF, Santa Clara, CA (US)

(21) Appl. No.: 19/102,604

(22) PCT Filed: Aug. 23, 2023
(86) PCT No.: PCT/US2023/072767

§ 371 Date: Feb. 10, 2025

Related U.S. Application Data
(60) Provisional application No. 63/376,201, filed on Sep. 19, 2022.

(51) Int. Cl. H01J 37/32

(52) U.S. Cl. CPC H01J 37/32495; H01J 37/32467; H01J 37/32559; H01J 37/32642

(57) ABSTRACT

One example provides a plasma-exposed part for a plasma processing tool. The plasma-exposed part comprises an etch-resistant material that has a lower etch rate than silicon or silicon carbide when exposed to plasma process gas chemistries comprising fluorine and/or oxygen. The etch-resistant material comprising one or more of (a) an oxide, a nitride, or an oxynitride of one or more of titanium, hafnium, zirconium, or tin, or (b) one or more of silicon or silicon carbide doped with one or more of titanium, hafnium, zirconium, or tin.

### BACKGROUND

Plasma processes are commonly used to remove materials from substrates in semiconductor fabrication processes. One example of a plasma process is reactive ion etching (RIE). RIE involves forming a plasma comprising chemically reactive gases. Ions of the reactive gases formed in the plasma react with a substrate in a processing chamber to form volatile products. The volatile products are then removed from the processing chamber in the gas phase.

### SUMMARY

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject matter is not limited to implementations that solve any or all disadvantages noted in any part of this disclosure.

One example provides a plasma-exposed part for a plasma processing tool. The plasma-exposed part comprises an etch-resistant material that has a lower etch rate than silicon or silicon carbide when exposed to plasma process gas chemistries comprising fluorine and/or oxygen. The etch-resistant material comprises one or more of (a) an oxide, a nitride, or an oxynitride of one or more of titanium, hafnium, zirconium, or tin, or (b) one or more of silicon or silicon carbide doped with one or more of titanium, hafnium, zirconium, or tin.

In some such examples, the etch-resistant material is configured to form a fluoride upon reacting with plasma process gas chemistries comprising fluorine. The fluoride has a boiling point of 1000 °C or lower.

In some such examples, alternatively or additionally the etch-resistant material comprises one or more of the oxide, the nitride, or the oxynitride of titanium or zirconium.

In some such examples, alternatively or additionally the etch-resistant material comprises the nitride of titanium or the nitride of zirconium.

In some such examples, a bulk portion and a surface of the plasma-exposed part alternatively or additionally are formed from the etch-resistant material.

In some such examples, the plasma-exposed part alternatively or additionally is an electrode, a plasma containment shroud, or an edge ring.

Another example provides a plasma processing tool comprising a processing chamber and a plasma-exposed part located within the processing chamber. The plasma-exposed part comprises an etch-resistant material that has a lower etch rate than silicon or silicon carbide when exposed to plasma process gas chemistries comprising fluorine and/or oxygen. The etch-resistant material comprises one or more of (a) an oxide, a nitride, or an oxynitride of one or more of titanium, hafnium, zirconium, or tin, or (b) one or more of silicon or silicon carbide doped with one or more of titanium, hafnium, zirconium, or tin.

In some such examples, the tool alternatively or additionally comprises a dielectric plasma etching tool.

In some such examples, alternatively or additionally the etch-resistant material is configured to form a fluoride upon reacting with plasma process gas chemistries comprising fluorine. The fluoride has a boiling point of 1000 °C or lower.

In some such examples, alternatively or additionally the plasma-exposed part comprises an outer layer supported by a bulk portion. The outer layer comprises the etch-resistant material.

In some such examples, alternatively or additionally the bulk portion comprises one or more of silicon, silicon carbide, or silicon oxide.

In some such examples, alternatively or additionally a bulk portion and a surface of the plasma-exposed part are formed from the etch-resistant material.

In some such examples, alternatively or additionally the plasma-exposed part is an electrode, a plasma containment shroud, or an edge ring.

Another example provides a plasma-exposed part for a plasma processing tool. The plasma-exposed part comprises a bulk portion and an outer layer supported by the bulk portion. The outer layer comprises an etch-resistant material that is different than a material of the bulk portion. The etch-resistant material is configured to etch at a lower rate in a selected plasma chemistry than silicon or silicon carbide.

In some such examples, alternatively or additionally the outer layer contacts the bulk portion.

In some such examples, alternatively or additionally the etch-resistant material comprises one or more of an oxide, a nitride, or an oxynitride of one or more of titanium, hafnium, zirconium, or tin.

In some such examples, the etch-resistant material alternatively or additionally comprises one or more of the oxide, the nitride, or the oxynitride of titanium or zirconium.

In some such examples, alternatively or additionally the etch-resistant material comprises one or more of silicon or silicon carbide doped with one or more of titanium, hafnium, zirconium, or tin.

In some such examples, alternatively or additionally the etch-resistant material is configured to form a fluoride upon reacting with plasma process gas chemistries comprising fluorine. The fluoride has a boiling point of 1000 °C or lower.

In some such examples, alternatively or additionally the bulk portion comprises one or more of silicon, silicon carbide, or silicon oxide.

In some such examples, alternatively or additionally the plasma-exposed part is an electrode, a plasma containment shroud, or an edge ring.

### BRIEF DESCRIPTION OF THE DRAWINGS

FIG. 1 shows a block diagram of an example plasma processing tool.

FIG. 2 schematically shows a bottom view of an example plasma containment shroud comprising an etch-resistant material.

FIG. 3 schematically shows a sectional side view taken along line 3-3 of FIG. 2.

FIG. 4 schematically shows a bottom view of an example inner electrode comprising an etch-resistant material.

FIG. 5 schematically shows a sectional side view taken along line 5-5 of FIG. 4.

FIG. 6 schematically shows a bottom view of an example outer electrode comprising an etch-resistant material.

FIG. 7 schematically shows a sectional side view taken along line 7-7 of FIG. 6.

FIG. 8 schematically shows a bottom view of an example edge ring comprising an etch-resistant material.

FIG. 9 schematically shows a sectional side view of the edge ring taken along line 9-9 of FIG. 8.

FIG. 10 schematically shows an example plasma containment shroud comprising a coating of an etch-resistant material.

FIG. 11 schematically shows an example inner electrode comprising a coating of an etch-resistant material.

FIG. 12 schematically shows an example outer electrode comprising a coating of an etch-resistant material.

FIG. 13 schematically shows an example edge ring comprising a coating of an etch-resistant material.

FIG. 14 schematically shows an example plasma containment shroud comprising a partial coating of an etch-resistant material.

FIG. 15 schematically shows an example inner electrode comprising a partial coating of an etch-resistant material.

FIG. 16 schematically shows an example outer electrode comprising a partial coating of an etch-resistant material.

FIG. 17 schematically shows an example edge ring comprising a partial coating of an etch-resistant material.

FIG. 18 shows a flow diagram depicting an example method for using a plasma-exposed part comprising an etch-resistant material.

### DETAILED DESCRIPTION

The term “atomic layer deposition” (ALD) may generally represent a process in which a film is formed on a surface in one or more individual layers by sequentially adsorbing a precursor conformally to the surface and reacting the adsorbed precursor to form a film layer. One example of an ALD process is plasma-enhanced ALD (PEALD). PEALD utilizes a plasma of a reactive gas to facilitate a chemical conversion of a precursor adsorbed to the film on the surface.

The term “bulk portion” may generally represent a majority of a mass of a component of a plasma processing tool. A bulk portion of a component may be coated with a coating comprising a different material than the bulk portion.

The term “chemical vapor deposition” (CVD) may generally represent a process in which a film is formed on a surface by sequentially adsorbing a precursor conformally to the surface and reacting the adsorbed precursor to form a film layer. One example of a CVD process is plasma-enhanced CVD (PECVD). PECVD utilizes a plasma of a reactive gas to facilitate a chemical conversion of a precursor adsorbed to the film on the surface.

The term “dielectric plasma etching process” may generally represent a plasma process for etching dielectric materials on a substrate.

The term “dielectric plasma etching tool” may generally represent a machine including a processing chamber and other hardware configured to enable plasma processes for etching dielectric materials on a substrate to be carried out in the processing chamber.

The term “edge ring” may generally represent a component of a plasma processing tool configured to encircle a substrate positioned on a substrate support of the plasma processing tool.

The term “electrode” may generally represent a component of a plasma processing tool configured to provide power to a plasma.

The term “etch” and variants thereof may generally represent removal of material from a structure due to exposure of the structure to a plasma in a plasma processing tool. Substrates and plasma processing tool components may be etched by a plasma in a plasma processing tool.

The term “etching agent” may generally represent a chemical substance used in a plasma processing gas mixture to remove materials from a substrate. Example etching agents may include fluorine-containing materials. Examples of fluorine-containing etching agents may include molecular fluorine (F₂), nitrogen trifluoride (NF₃), boron trifluoride (BF₃), sulfur hexafluoride (SF₆), and fluorocarbon compounds having a general formula CₐH_{b}F_{c}, where a=1-10.

The term “etch rate ratio” may generally represent a ratio of an etch distance as a function of time for a first material compared to an etch distance as a function of time for a second material.

The term “etch-resistant material” may generally represent a material that has a lower etch rate than silicon or silicon carbide when exposed to plasma process gas chemistries comprising fluorine and/or oxygen.

The term “fluoride” may generally represent a chemical species comprising a fluorine anion.

The term “plasma process gas chemistries comprising fluorine and/or oxygen” may generally represent a plasma processing environment comprising a fluorine-containing material and/or an oxygen-containing material for chemical etching.

The term “nitride of one or more of titanium, hafnium, zirconium, or tin” may generally represent a material comprising one or more of titanium cations, hafnium cations, zirconium cations, or tin cations, and also comprising nitrogen anions.

The term “outer layer” may generally represent a coating on a plasma-exposed part having a different composition than a bulk portion of the plasma-exposed part. At least a portion of the outer layer is exposed to a plasma during plasma processing. In some examples, an outer layer may be coated directly on a bulk portion of a plasma-exposed part. In other examples, one or more intervening layers may be disposed between an outer layer and a bulk portion of a plasma-exposed part. An outer layer may coat an entire surface of a plasma-exposed part, or a portion of a surface of a plasma-exposed part.

The term “oxide of one or more of titanium, hafnium, zirconium, or tin” may generally represent a material comprising one or more of titanium cations, hafnium cations, zirconium cations, or tin cations, and also comprising oxygen anions.

The term “oxynitride of one or more of titanium, hafnium, zirconium, or tin” may generally represent a material comprising one or more of titanium cations, hafnium cations, zirconium cations, or tin cations, and also comprising nitrogen and oxygen anions.

The term “made only of” may generally represent a part in a plasma processing tool that is formed from a named material, but that may contain trace impurities of other materials.

The term “plasma chemistry” may generally represent a chemical environment within a processing chamber during a plasma process.

The term “plasma confinement area” may generally represent a volume of space within a processing chamber that is at least partially enclosed by plasma-exposed parts.

The term “plasma containment shroud” may generally represent a component within a processing chamber that forms a side portion of a plasma confinement area.

The term “plasma-exposed part” may generally represent a part in a plasma processing tool that is exposed to a plasma during plasma processing.

The term “plasma-exposed surface” may generally represent a surface of a plasma-exposed part that is exposed to a plasma during plasma processing.

The term “plasma processing tool” may generally represent a machine including a processing chamber and other hardware configured to enable plasma processes to be carried out in the processing chamber.

The term “processing chamber” may generally represent an enclosure in which plasma processing is performed on substrates. The pressure, temperature, atmospheric composition, and other conditions within a processing chamber may be controllable to perform plasma processes.

The terms “reactive ion etching” and “RIE” may generally represent an etching process that uses a plasma to form reactive ion species to etch a substrate.

The term “silicon doped with one or more of titanium, hafnium, zirconium, or tin” may generally represent elemental silicon comprising a concentration of one or more of titanium, hafnium, zirconium, or tin atoms in any suitable oxidation state(s).

The term “silicon carbide doped with one or more of titanium, hafnium, zirconium, or tin” may generally represent silicon carbide comprising a concentration of one or more of titanium, hafnium, zirconium, or tin atoms in any suitable oxidation state(s).

The term “substrate” may generally represent any object which is a target of a plasma process. For example, a plasma etching process removes material from a substrate.

A plasma etching process utilizes a plasma to provide energy for removing material from a substrate. For example, in a RIE process, one or more etching agents are introduced into the plasma. The plasma forms reactive ions from the one or more etching agents. The reactive ions react with a substrate surface material to form volatile products. The volatile products are then removed from the processing chamber in the gas phase.

In some examples, the etching agent may comprise a fluorine-containing gas. The plasma creates reactive fluorine-containing species. The reactive fluorine-containing species react with materials such as silicon oxide or silicon nitride to form volatile products such as SiF₄. However, plasma etching conditions also may etch plasma-exposed parts in the processing chamber. For example, a dielectric plasma etching tool may utilize plasma-exposed parts comprising materials such as silicon or silicon carbide. Silicon and silicon carbide are etched by the etching agents used to etch dielectrics, although at a lower rate. The etching may result from chemical as well as physical effects such as sputtering.

Over time, the material loss on the plasma-exposed parts may affect plasma etching processes. As such, the plasma-exposed parts are replaced periodically as a part of scheduled maintenance. The useful lifetime of a plasma-exposed part impacts a frequency at which the plasma-exposed part is replaced. The useful lifetime of the plasma-exposed part also impacts a mean time between cleaning of the plasma-exposed part. A plasma-exposed part that is more frequently replaced as a function of total usage time may increase a cost of ownership of the plasma processing tool compared to a part that is less frequently replaced. In some scenarios, the lifetime of silicon or silicon carbide plasma-exposed parts may be around 2000 radio frequency (RF) hours. Further, a plasma-exposed part that etches at a relatively faster rate may lead to more frequent processing chamber cleanings. More frequent cleanings as a function of tool usage time also may increase a cost of operation of the plasma processing tool relative to longer times between cleanings.

Accordingly, examples are disclosed that relate to a plasma-exposed part comprising an etch-resistant material to help extend a useful lifetime of the plasma-exposed part. The etch-resistant material disclosed herein has a lower etch rate than silicon or silicon carbide when exposed to processing gas comprising fluorine and/or oxygen. In some instances, etch rate is also called erosion rate, which indicates etching distance over time, for example micrometer (um) over radio frequency hours (RFH), or um/RFH. Plasma-exposed parts made with lower etch rate materials may have a longer useful life. Further, these parts may help reduce a frequency of cleanings as a function of tool usage time, which in turn reduces the overall tool downtime. In some examples, the etch-resistant material comprises one or more of an oxide, a nitride, or an oxynitride of one or more of titanium, hafnium, zirconium, or tin. In other examples, the etch-resistant material comprises one or more of silicon or silicon carbide doped with one or more of titanium, hafnium, zirconium, or tin. In some examples, a bulk portion and a surface of the plasma-exposed part are formed from the etch-resistant material. In other examples, the plasma-exposed part comprises a bulk portion coated with an outer layer comprising the etch-resistant material. While described herein in the context of a dielectric plasma etching process, the plasma-exposed parts comprising the etch-resistant material may be used in any suitable plasma process.

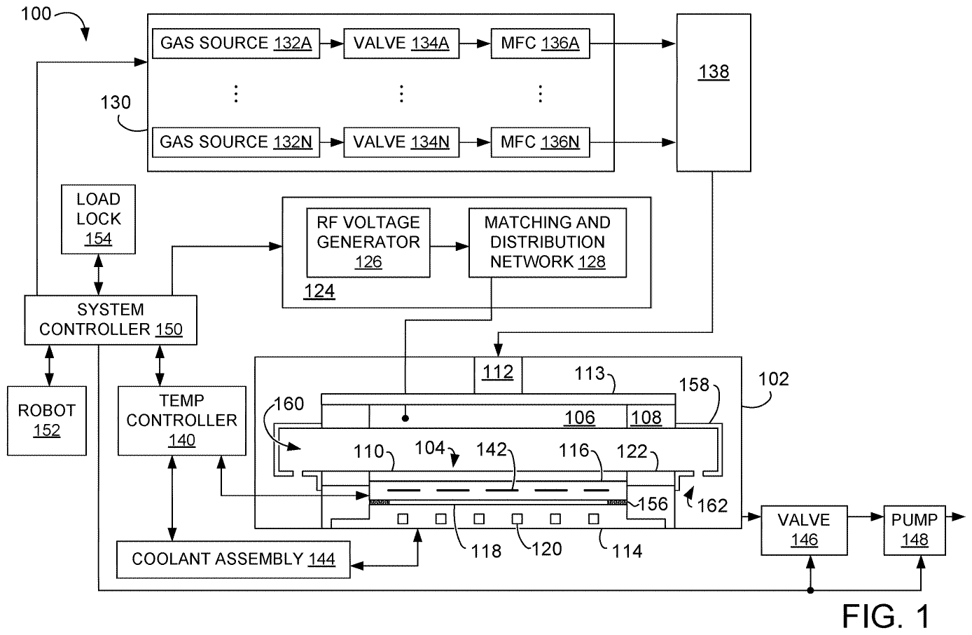

Prior to discussing these examples in more detail, FIG. 1 schematically shows an example plasma processing tool 100 in the form of a plasma etching tool. Plasma processing tool 100 includes a processing chamber 102. Plasma processing tool 100 further includes a substrate support 104 disposed within processing chamber 102. During operation, a substrate 110 is arranged on substrate support 104. Substrate support 104 may include a pedestal, electrostatic chuck, and/or any other suitable components for supporting substrate 110.

Plasma processing tool 100 further comprises an inner electrode 106 and an outer electrode 108. The use of separate components for inner electrode 106 and outer electrode 108 instead of a unitary, larger electrode allows inner electrode 106 and outer electrode 108 to be replaced at different frequencies. For example, inner electrode 106 may be replaced more frequently than outer electrode 108.

In the depicted example, inner electrode 106 and outer electrode 108 are incorporated in a showerhead 112 configured to introduce and distribute process gases, such as a fluorine-containing material for chemical etching, an inert gas as a diluent gas, a purge gas, and/or a sputtering gas. A substrate-facing surface of showerhead 112 includes a plurality of holes through which the process gases flow.

A heater 113 is arranged above inner electrode 106 and outer electrode 108. Heater 113 is thermally coupled to inner electrode 106 and outer electrode 108. Heater 113 is used to control a temperature of inner electrode 106 and/or outer electrode 108 during substrate processing.

Substrate support 104 includes a conductive baseplate 114 that acts as a lower electrode. Baseplate 114 supports a ceramic layer 116. In some examples, ceramic layer 116 can comprise a heater. An example heater comprises a ceramic multi-zone heating plate. A thermal resistance layer 118 is arranged between ceramic layer 116 and baseplate 114. Baseplate 114 includes one or more coolant channels 120 for flowing coolant through baseplate 114. Substrate support 104 further includes an edge ring 122 configured to encircle substrate 110.

An RF generating system 124 generates and outputs an RF voltage to inner electrode 106 and outer electrode 108. In some examples, the RF voltage oscillates around a bias voltage. Baseplate 114 can be direct current (DC) grounded, alternating current (AC) grounded, or floating. RF generating system 124 includes an RF voltage generator 126 configured to generate the RF voltage that is fed using a matching and distribution network 128 to inner electrode 106 and outer electrode 108. In other examples, the plasma can be generated inductively, remotely, or using any other suitable method. Examples of RF generating system 124 comprise a capacitively coupled plasma (CCP) system, transformer coupled plasma (TCP) systems, CCP cathode systems, and remote microwave plasma generation and delivery systems. In other examples, the RF voltage can be sent to baseplate 114, and inner electrode 106 and outer electrode 108 can be DC grounded, AC grounded, or floating.

A gas delivery system 130 includes gas sources 132A and 132N (collectively gas sources 132), where N indicates an arbitrary number of gas sources in addition to gas source 132A that is equal to or greater than zero. Gas sources 132 supply one or more precursors and/or mixtures thereof. Gas sources 132 can also supply a purge gas. Vaporized precursors can also be used. Gas sources 132 are connected by valves 134A and 134N (collectively valves 134) and mass flow controllers (MFC) 136A and 136N (collectively mass flow controllers 136) to a manifold 138. Example gas sources include an etching agent source and an inert gas source. An output of manifold 138 is fed to processing chamber 102, such as to showerhead 112. Gas delivery system 130 further can help to control a pressure of processing chamber 102. In some examples, a pressure of processing chamber 102 may be on the order of millitorrs. In other examples, gas delivery system 130 may include one gas source 132, valve 134, and/or MFC 136.

A temperature controller 140 is connected to a plurality of thermal control elements (TCEs) 142 arranged in ceramic layer 116. Temperature controller 140 is used to control plurality of heating elements 142 to control a temperature of substrate support 104 and substrate 110. Further, temperature controller 140 communicates with a coolant assembly 144 to control coolant flow through coolant channels 120. In some examples, coolant assembly 144 can include a coolant pump and reservoir. Temperature controller 140 operates coolant assembly 144 to selectively flow the coolant through coolant channels 120 to cool substrate support 104.

A valve 146 and a pump 148 can be used to evacuate reactants from processing chamber 102. Further, a system controller 150 is configured to controls components of plasma processing tool 100. A robot 152 delivers substrates onto, and removes substrates from, substrate support 104. For example, robot 152 transfers substrates between substrate support 104 and a load lock 154. Although shown as separate controllers, temperature controller 140 can be implemented within system controller 150. Further, a protective seal 156 is provided around a perimeter of thermal resistance layer 118 between ceramic layer 116 and baseplate 114. In other examples, protective seal 156 may be omitted.

Processing chamber 102 further includes a plasma containment shroud 158. Plasma containment shroud 158 is arranged around outer electrode 108 and edge ring 122. In the depicted example, inner electrode 106, outer electrode 108, plasma containment shroud 158, and edge ring 122 confine the plasma within a plasma confinement area 160. In some examples, plasma containment shroud 158 is electrically connected to outer electrode 108 and inner electrode 106. Plasma containment shroud 158 includes one or more slots 162 to provide fluid communication between plasma confinement area 160 and an environment external to plasma containment shroud 158. During operation, one or more of plasma containment shroud 158, inner electrode 106, outer electrode 108, or edge ring 122 may be exposed to plasma process gas chemistries comprising fluorine and/or oxygen. As such, these parts are referred to collectively as plasma-exposed parts. In other examples, any other suitable plasma-exposed parts may be used to confine a plasma within a plasma confinement area.

FIG. 1 is illustrative. In other examples, a plasma processing tool may comprise any other components suitable for performing a plasma process. Other example components may include a remote plasma generation and delivery system. Further, in some examples, plasma processing tool 100 may omit one or more components illustrated. While discussed herein in the context of a plasma etching tool, other plasma processing tools may be used to implement a suitable plasma process. Other examples of plasma processing tools may include PEALD and PECVD tools. Such tools may be configured to perform in-situ etching in some examples.

As previously mentioned, fluorine-containing etching agents used for performing dielectric etching may also etch/erode plasma-exposed parts. Many known plasma-exposed parts for plasma processing tools are made of silicon and/or silicon carbide. The silicon and/or silicon carbide would experience material loss from exposure to plasma process gas chemistries over time. Such plasma-exposed parts would need to be replaced when the material loss reaches a replacement threshold condition. To reduce the replacement frequency, examples of the present disclosure introduce plasma-exposed parts comprising materials that are more etch-resistant than silicon or silicon carbide.

Accordingly, a plasma-exposed part according to the present disclosure comprises an etch-resistant material that is more etch-resistant than silicon or silicon carbide. As mentioned above, the term “etch-resistant material” as used herein may generally represent a material that has a lower etch rate than silicon or silicon carbide when exposed to plasma process gas chemistries comprising fluorine and/or oxygen. Further, such a configuration may help to extend a useful lifetime of the plasma-exposed part over a plasma-exposed part formed from silicon and/or silicon carbide. Further, the extended useful lifetime may help to reduce a cost of ownership of a plasma processing tool. In some examples, the etch-resistant material may comprise one or more of an oxide, a nitride, or an oxynitride of one or more of titanium, hafnium, zirconium, or tin. In other examples, the etch-resistant material may comprise one or more of silicon or silicon carbide doped with one or more of titanium, hafnium, zirconium, or tin. Such materials may have a lower etch rate in plasma process gas chemistries comprising fluorine and/or oxygen than silicon or silicon carbide. This may help to provide a longer useful lifetime for plasma-exposed parts comprising the etch-resistant material than for parts made only of silicon or silicon carbide.

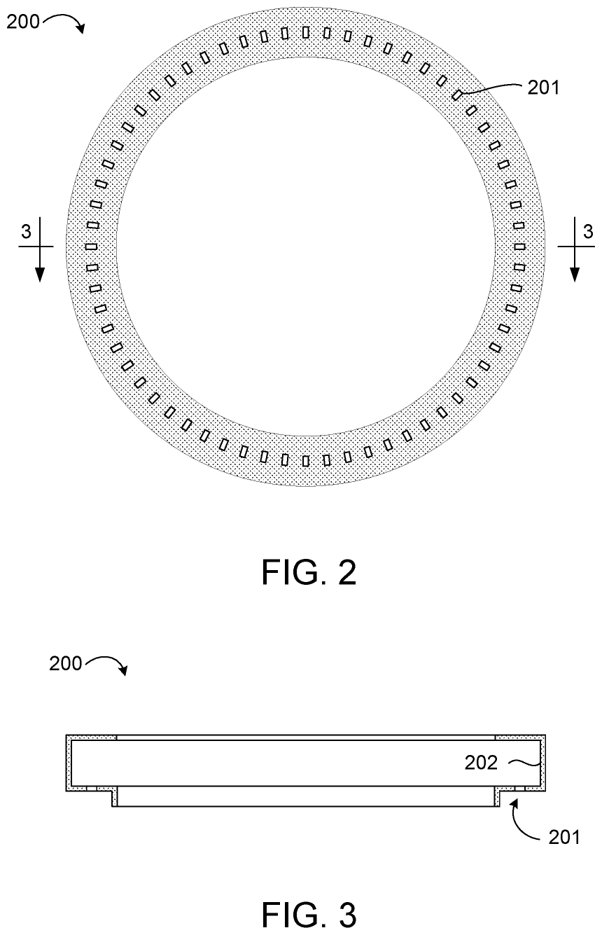

As mentioned above, in some examples, a bulk portion of a plasma-exposed part, including a plasma-exposed surface, comprises the etch-resistant material. FIG. 2 schematically shows a bottom view of an example plasma containment shroud 200 comprising an etch-resistant material. FIG. 3 schematically shows a sectional side view of plasma containment shroud 200 taken along line 3-3 of FIG. 2. Plasma containment shroud 200 is an example of plasma containment shroud 158. Further, slots 201 are examples of slots 162. As illustrated, a bulk of plasma containment shroud 200, including a plasma-exposed surface 202 illustrated in FIG. 3, is formed from the etch-resistant material.

Plasma containment shroud 200 and other plasma-exposed parts may be manufactured using any suitable method. In some examples, plasma containment shroud 200 or other plasma exposed part may be formed through hot-pressing of a powder of the etch-resistant material. Hot pressing comprises the application of pressure during sintering of a powder comprising the etch-resistant material. The application of pressure during sintering of the powder of the etch-resistant material may allow for faster formation of plasma containment shroud 200 than heat sintering without applied pressure. In other examples, plasma containment shroud 200 may be formed by spark plasma sintering of the etch-resistant material. The spark plasma sintering may be performed on the etch-resistant material in a compacted dry powder form. In further examples, plasma containment shroud 200 or other plasma-exposed part may be formed using other suitable ceramic processing methods, such as calcination of suitable starting materials, sintering under atmospheric pressure, additive manufacturing, and annealing. In further examples, the doped silicon plasma containment shroud or other plasma-exposed part may be formed using additive manufacturing.

As mentioned above, in other examples, plasma containment shroud 200 or other plasma exposed part may be formed from silicon doped with one or more of titanium, hafnium, zirconium, or tin. A doped silicon plasma containment shroud may be formed in any suitable manner. In some examples, the dopants may be added during manufacturing of the silicon. For example, the silicon may be doped when manufacturing a silicon ingot. In such examples, the silicon ingot may comprise a doping percentage of around 5 atomic % or less. In other examples, the silicon ingot may comprise any other suitable concentration of dopant. The silicon ingot then can be machined to form plasma containment shroud 200. In other examples, elemental silicon may be melted. The silicon then is doped while molten and poured into a casting mold. The molded silicon is then cooled to form plasma containment shroud 200. In some such examples, annealing may be performed to lower internal stresses of the silicon form in plasma containment shroud 200. In other examples, the plasma containment shroud or other plasma exposed part may be formed from silicon carbide doped with one or more of titanium, hafnium, zirconium, or tin.

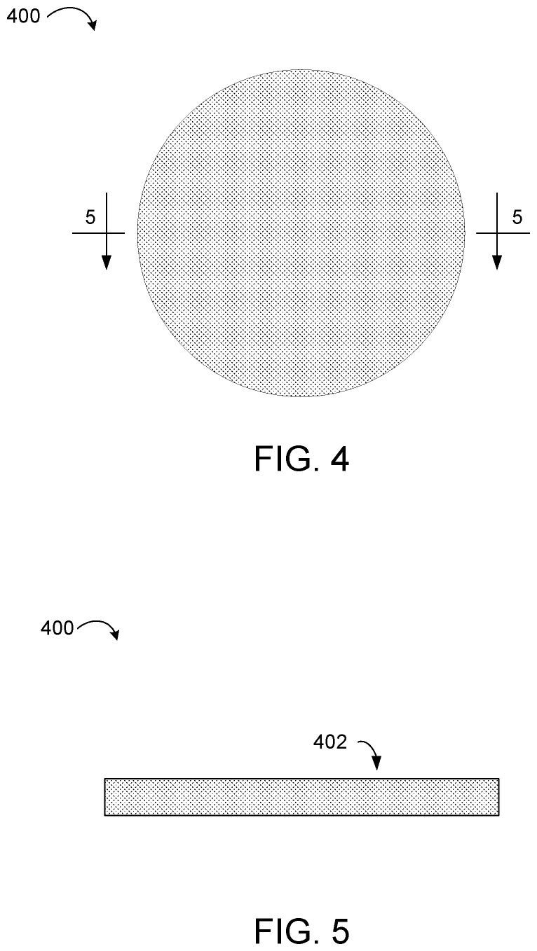

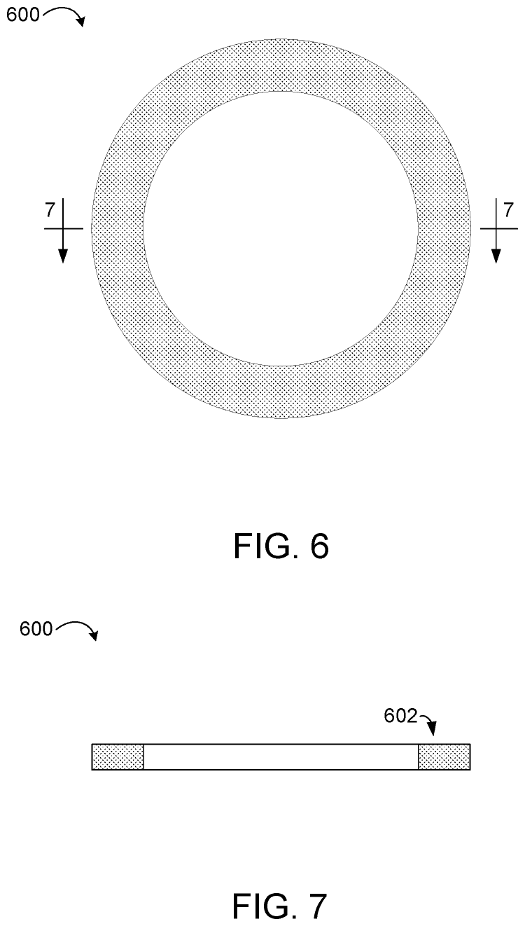

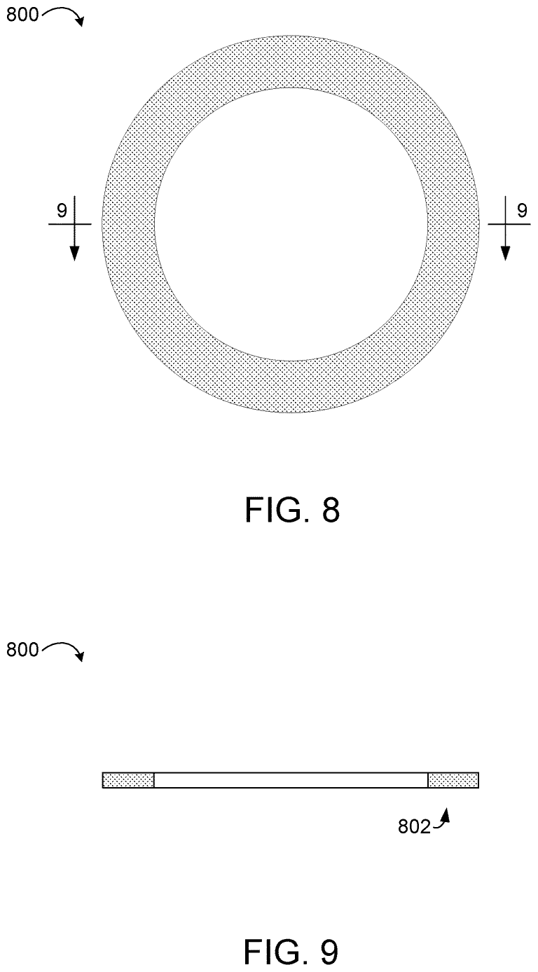

Other examples of plasma-exposed parts are illustrated in FIGS. 4-9. More particularly, FIG. 4 schematically shows a bottom view of an example inner electrode 400. Inner electrode 400 is an example of inner electrode 106. FIG. 5 schematically shows a sectional side view of inner electrode 400 taken along line 5-5 of FIG. 4. As shown, a bulk of inner electrode 400 including a plasma-exposed surface 402 is formed from the etch-resistant material. Next, FIG. 6 schematically shows a bottom view of an example outer electrode 600 comprising the etch-resistant material. Outer electrode 600 is an example of outer electrode 108. FIG. 7 schematically shows a sectional side view of outer electrode 600 taken along line 7-7 of FIG. 6. As shown, a bulk of outer electrode 600 including a plasma-exposed surface 602 is formed from the etch-resistant material. Next, FIG. 8 schematically shows a bottom view of an example edge ring 800 comprising the etch-resistant material. Edge ring 800 is an example of edge ring 122. FIG. 9 schematically shows a sectional side view of edge ring 800 taken along line 9-9 of FIG. 8. As shown, a bulk of edge ring 800, including a plasma-exposed surface 802, is formed from the etch-resistant material.

In other examples, a plasma-exposed part according to the present disclosure may comprise an outer layer comprising a plasma-exposed surface formed from an etch-resistant material, and a bulk portion made from a different material. The bulk portion supports the outer layer. Such a configuration may help to extend a useful lifetime of the plasma-exposed part over a plasma-exposed part made only of silicon and/or silicon carbide. Further, the plasma-exposed part comprising the bulk portion and the outer layer may cost less than a plasma-exposed part comprising a bulk portion formed from the etch-resistant material.

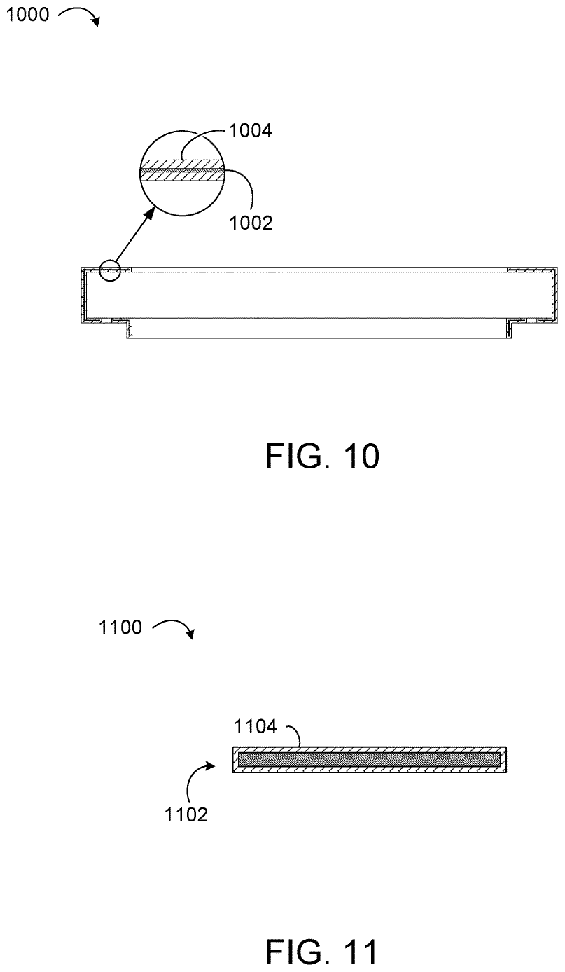

FIG. 10 shows an example plasma containment shroud 1000 comprising a bulk portion 1002 and an outer layer 1004. Plasma containment shroud 1000 is an example of plasma containment shroud 158. In the depicted example, outer layer 1004 contacts bulk portion 1002. In other examples, one or more intervening layers may be disposed between outer layer 1004 and bulk portion 1002. In the depicted example, outer layer 1004 coats an entire surface of plasma containment shroud 1000. In other examples, outer layer 1004 may coat a portion of the surface of plasma containment shroud 1000. In yet other examples, outer layer 1004 may vary in thickness spatially across the surface of plasma containment shroud 1000.

Outer layer 1004 comprises an etch-resistant material. The etch-resistant material is configured to etch at a lower rate in plasma process gas chemistries comprising fluorine and/or oxygen than silicon or silicon carbide. In some examples, the etch-resistant material may comprise one or more of an oxide, a nitride, or an oxynitride of one or more of titanium, hafnium, zirconium, or tin. In other examples, the etch-resistant material can comprise one or more of silicon or silicon carbide doped with one or more of titanium, hafnium, zirconium, or tin. The lower etch rate may help to extend a useful lifetime of plasma containment shroud 1000.

Outer layer 1004 may be deposited onto bulk portion 1002 in any suitable manner. Examples include ALD, CVD, sputtering, pulsed laser deposition, thermal spray, plasma-spray deposition, or a combination thereof. In other examples, outer layer 1004 may be applied as a dispersion in a solvent. The dispersion may be applied by spin coating, spray coating, doctor blade, dip coating, or other suitable method. The solvent may then evaporate and the etch-resistant material may be processed to form outer layer 1004. For example, after the solvent is evaporated, the etch-resistant material may be processed by calcining, sintering, and/or annealing.

Bulk portion 1002 comprises a different material than outer layer 1004. In some examples, bulk portion 1002 may comprise one or more of silicon, silicon carbide, or silicon oxide. In other examples, bulk portion 1002 may comprise graphite, a metal, silicon, silicon carbide, or a suitable dielectric ceramic material other than those listed above. Bulk portion 1002 may be formed by machining, die casting, and/or any other suitable method(s).

As previously mentioned, plasma containment shroud 1000 can be electrically coupled to other components in a processing chamber. As such, the etch-resistant material may be selected to have a suitable electrical conductivity for a plasma etching process to be performed. In some examples, an etch-resistant material selected for a desired etch resistance may not comprise a sufficient conductivity. In such examples, outer layer 1004 may be applied in a sufficiently thin coating, and the material of bulk portion 1002 may be selected for conductivity. In some examples, the sufficiently thin coating may comprise a thickness of 400 micrometers or less.

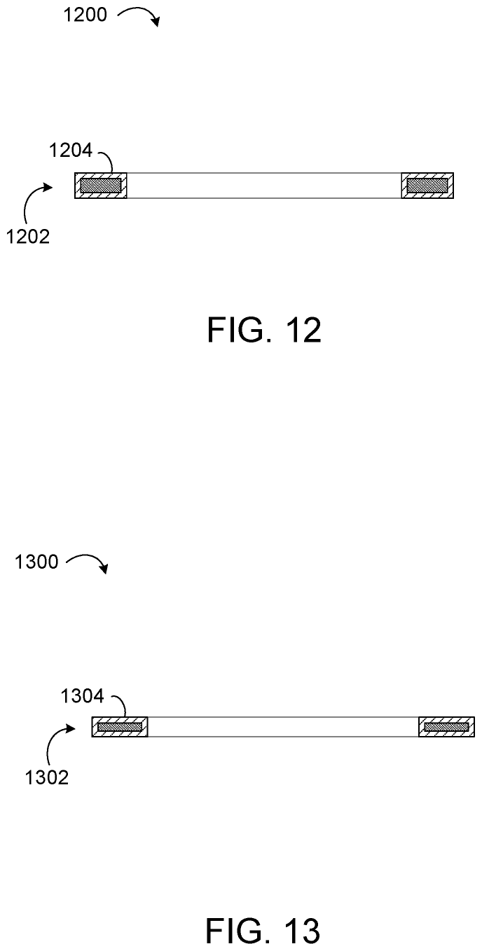

FIGS. 11-13 show other example plasma-exposed parts including an outer layer comprising an etch-resistant material supported by a bulk portion comprising a different material. FIG. 11 schematically shows an example inner electrode 1100 comprising a bulk portion 1102 supporting an outer layer 1104 comprising an etch-resistant material. Inner electrode 1100 is an example of inner electrode 106. Next, FIG. 12 schematically shows an example outer electrode 1200 comprising a bulk portion 1202 supporting an outer layer 1204 comprising an etch-resistant material. Outer electrode 1200 is an example of outer electrode 108. Next, FIG. 13 schematically shows an example edge ring 1300 comprising a bulk portion 1302 supporting an outer layer 1304 comprising an etch-resistant material. Edge ring 1300 is an example of edge ring 122.

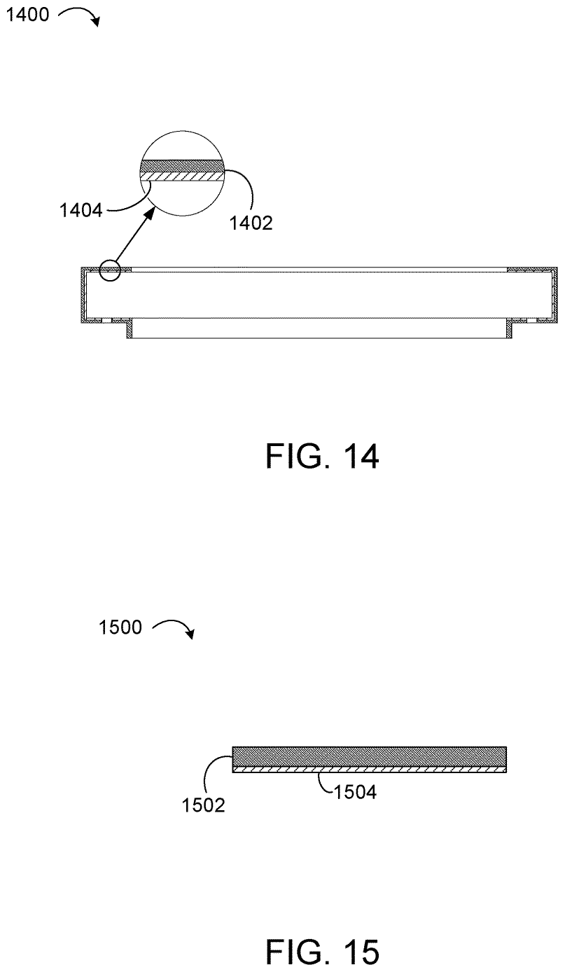

As mentioned above, in some examples a plasma-exposed part may be partially coated with an etch-resistant material. FIGS. 14-17 show example plasma-exposed parts including a partial coating of an etch-resistant material supported by a bulk portion comprising a different material. More particularly, FIG. 14 shows an example plasma containment shroud 1400 comprising a bulk portion 1402 and an outer layer 1404 comprising a partial coating of an etch-resistant material. Outer layer 1404 coats a plasma-exposed surface of plasma containment shroud 1400. Plasma containment shroud 1400 is an example of plasma containment shroud 158. In the depicted example, outer layer 1404 contacts bulk portion 1402. In other examples, one or more intervening layers may be disposed between outer layer 1404 and bulk portion 1402. In the depicted example, outer layer 1404 has a uniform thickness. In other some examples, outer layer 1404 may vary in thickness spatially across the plasma-exposed surface of plasma containment shroud 1400.

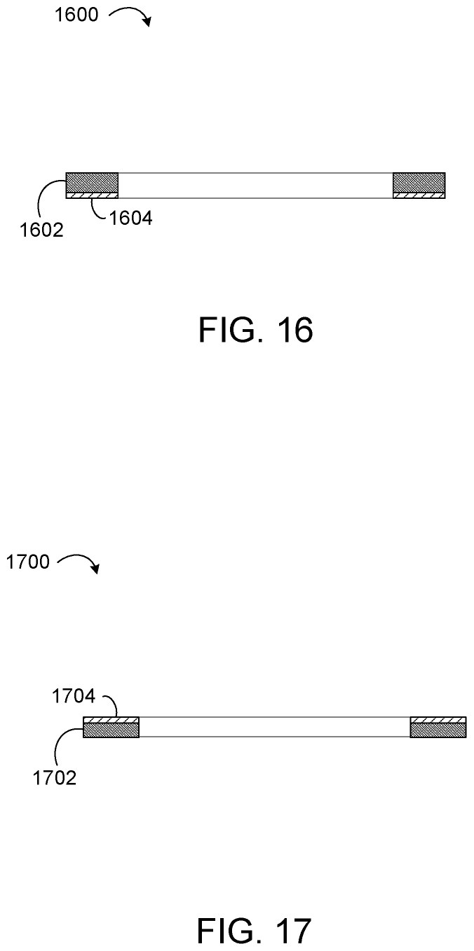

FIG. 15 schematically shows an example inner electrode 1500 comprising a bulk portion 1502 supporting a partial coating of an outer layer 1504 comprising an etch-resistant material. Inner electrode 1500 is an example of inner electrode 106. Next, FIG. 16 schematically shows an example outer electrode 1600 comprising a bulk portion 1602 supporting a partial coating of an outer layer 1604 comprising an etch-resistant material. Outer electrode 1600 is an example of outer electrode 108. Next, FIG. 17 schematically shows an example edge ring 1300 comprising a bulk portion 1702 supporting a partial coating of an outer layer 1704 comprising an etch-resistant material. Edge ring 1700 is an example of edge ring 122.

As previously mentioned, examples of the etch-resistant material comprise one or more of an oxide, a nitride, or an oxynitride of one or more of titanium, hafnium, zirconium, tin, or any suitable combination thereof. In some examples, the etch-resistant material comprises one or more of the oxide, the nitride, or the oxynitride of titanium or zirconium.

The etch-resistant material may be selected based on an etch rate compared to silicon in plasma process gas chemistries comprising fluorine and/or oxygen. As a specific illustrative example, an inner electrode comprising TiN as an etch-resistant material may comprise an etch rate ratio of 0.8 compared to silicon in the plasma process gas chemistries comprising fluorine and/or oxygen. As another example, an inner electrode comprising Zr₅N₅O₂ as an etch-resistant material may comprise an etch rate ratio of 0.8 compared to silicon in the plasma process gas chemistries comprising fluorine and/or oxygen. As yet another example, an inner electrode comprising ZrN as an etch-resistant material may comprise an etch rate ratio of 0.9 compared to silicon in the plasma process gas chemistries comprising fluorine and/or oxygen. An etch rate ratio of less than 1.0 compared to silicon may result in a longer useful lifetime of the plasma-exposed part compared to a part made from silicon. Table 1 lists examples of various etch-resistant materials and associated calculated etch rates.

TABLE 1

| Etch-resistant | Calculated etch rate | Etch rate ratio compared |
|---|---|---|
| material | (um/RFH) | to silicon |
| HfₓN_{y} | 0.14-0.26 | 0.34-0.61 |
| HfₓO_{y}N_{z} | 0.16 | 0.38-0.39 |
| HfO₂ | 0.07-0.24 | 0.16-0.55 |
| HfZrO₄ | 0.07-0.14 | 0.16-0.33 |
| HfTiO₄ | 0.28-0.29 | 0.65-0.67 |
| HfSiO₄ | 0.40 | 0.93 |
| HfTiN₂ | 0.23 | 0.54 |
| TiN | 0.77-0.79 | 1.8 |
| ZrₓN_{y} | 0.17-0.27 | 0.40-0.63 |
| ZrₓN_{y}O_{z} | 0.20-0.21 | 0.8 |
| ZrO₂ | 0.08-0.52 | 0.18-1.21 |
| ZrTiN₂ | 0.27 | 0.64 |
| SiC | 3.5-3.6 | 8.3-8.4 |
| Si | 0.42 | 1 |

The etch rate ratio of the plasma-exposed part may vary depending on an applied bias voltage of the plasma-exposed part, a temperature of the plasma-exposed part, a percent oxygen gas flow, and/or other process parameters. The illustrated calculated values may not be representative of the erosion for all plasma-exposed locations in a chamber, as the process conditions can vary between the parts. Further, etch rates for materials may vary based upon variations in stoichiometry and structure (for example, grain size and/or crystal structure).

As previously mentioned, an etch-resistant material of a plasma-exposed part may be selected to form a fluoride upon reacting with the plasma process gas chemistries comprising fluorine. In some examples, the fluoride may be a volatile product that is removed from the processing chamber in the gas phase. In some such examples, the fluoride may have a boiling point of 1000 °C or lower. Such a configuration may help to remove the fluoride from the processing chamber during processing or during a cleaning performed post-processing. In contrast, fluorides having boiling points higher than 1000 °C may not be sufficiently volatile to remove from a processing chamber. Thus, such fluorides may pose risks of particulate formation. As a specific example, when the etch-resistant material comprises ZrN and/or Zr₅N₅O₂, the fluoride formed may comprise ZrF₄. ZrF₄ has a boiling point of about 910 °C.

In some examples, more than one fluoride may form upon a reaction between the etch-resistant material and the plasma process gas chemistries comprising fluorine. For example, TiN may form one or more of TiF₄, TiF₃, TiOF₂, and/or TiOF. However, such titanium compounds may over time further react to form TiF₄, as fluorine radicals in the etching plasma can oxidize TiF₄, TiF₃, TiOF₂, and/or TiOF to TiF₄. TiF₄ has a boiling point of about 284 °C. Thus, such titanium fluorides may be used as the etch-resistant material for a plasma-exposed part.

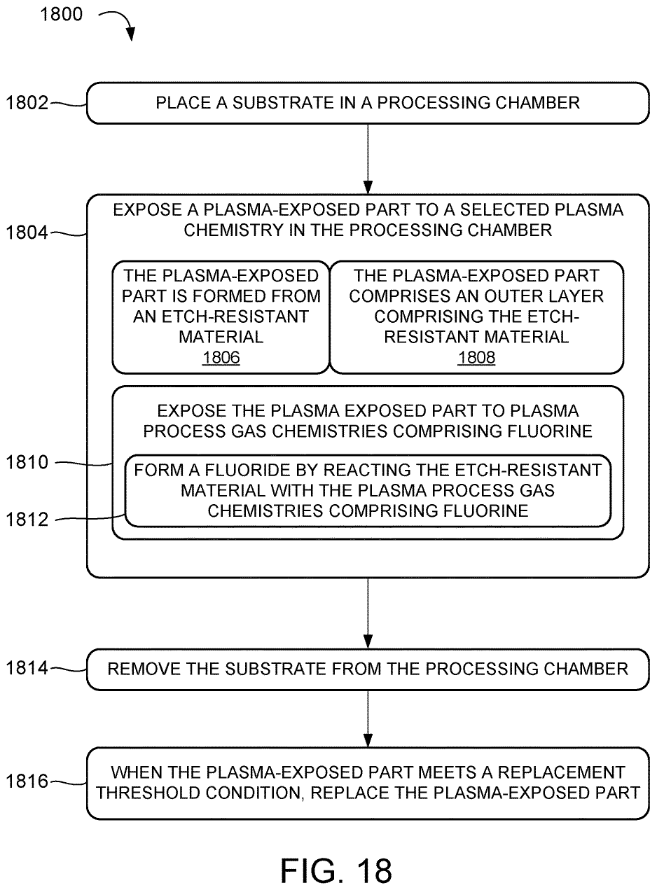

Plasma-exposed parts comprising an etch-resistant material as described herein may be used in any suitable plasma processing tool. FIG. 18 illustrates a flow diagram of an example method 1800 for using such a plasma-exposed part. Method 1800 may be performed on any suitable plasma processing tool, such as plasma processing tool 100, for example. Other examples include PECVD tools and PEALD tools. Method 1800 comprises, at 1802, placing a substrate in a processing chamber of the plasma processing tool. Method 1800 further comprises, at 1804, exposing a plasma-exposed part of the plasma processing tool to a selected plasma chemistry in the processing chamber. The plasma-exposed part comprises an etch-resistant material that has a lower etch rate than silicon or silicon carbide when exposed to the selected plasma chemistry. The etch-resistant material may comprise any suitable material with a lower etch rate than silicon or silicon carbide when exposed to plasma process gas chemistries comprising fluorine and/or oxygen. In some examples, the plasma-exposed part may be one or more of an inner electrode, an outer electrode, a plasma containment shroud, or an edge ring. In other examples, the plasma-exposed part may comprise any other suitable component. In some examples, a bulk and a surface of the plasma-exposed part may be formed from the etch-resistant material, as indicated at 1806. In other examples, the plasma-exposed part may comprise a bulk layer supporting an outer layer comprising the etch-resistant material, as indicated at 1808.

Continuing, exposing the plasma-exposed part to the selected plasma chemistry may comprise exposing the plasma-exposed part to plasma process gas chemistries comprising fluorine, as indicated at 1810. As illustrated at 1812, this forms a fluoride by reacting the etch-resistant material with the plasma process gas chemistries comprising fluorine. In some examples, the fluoride has a boiling point of 1000 °C or lower. Such a configuration may help to remove the fluoride from the processing chamber in the gas phase. While the etch-resistant material is etched by the plasma process gas chemistries comprising fluorine, the etch-resistant material etches at a lower rate than silicon or silicon carbide. Thus, the plasma-exposed part comprising the etch-resistant material would have a longer useful lifetime than a comparable part made from silicon.

Continuing, method 1800 comprises, at 1814, removing the substrate from the processing chamber. Method 1800 further comprises, at 1816, when the plasma-exposed part meets a replacement threshold condition, replacing the plasma-exposed part. In some examples, an edge ring may meet a replacement threshold condition faster than an inner electrode and then followed by a containment shroud. In some examples, when the replacement threshold condition is not met, method 1800 may return to 1802. In other examples, after the plasma-exposed part is replaced, method 1800 may return to 1802.

It will be understood that the configurations and/or approaches described herein are exemplary in nature, and that these specific embodiments or examples are not to be considered in a limiting sense, because numerous variations are possible. The specific routines or methods described herein may represent one or more of any number of processing strategies. As such, various acts illustrated and/or described may be performed in the sequence illustrated and/or described, in other sequences, in parallel, or omitted. Likewise, the order of the above-described processes may be changed.

The subject matter of the present disclosure includes all novel and non-obvious combinations and sub-combinations of the various processes, systems and configurations, and other features, functions, acts, and/or properties disclosed herein, as well as any and all equivalents thereof.

1. A plasma-exposed part for a plasma processing tool, the plasma-exposed part comprising:
an etch-resistant material that has a lower etch rate than silicon or silicon carbide when exposed to plasma process gas chemistries comprising fluorine and/or oxygen, the etch-resistant material comprising one or more of (a) an oxide, a nitride, or an oxynitride of one or more of titanium, hafnium, zirconium, or tin, or (b) one or more of silicon or silicon carbide doped with one or more of titanium, hafnium, zirconium, or tin.

2. The part of claim 1, wherein the etch-resistant material is configured to form a fluoride upon reacting with the plasma process gas chemistries comprising fluorine, the fluoride has a boiling point of 1000 °C or lower.

3. The part of claim 1, wherein the etch-resistant material comprises one or more of the oxide, the nitride, or the oxynitride of titanium or zirconium.

4. The part of claim 3, wherein the etch-resistant material comprises the nitride of titanium or the nitride of zirconium.

5. The part of claim 1, wherein a bulk portion and a surface of the plasma-exposed part are formed from the etch-resistant material.

6. The part of claim 1, wherein the plasma-exposed part is an electrode, a plasma containment shroud, or an edge ring.

7. A plasma processing tool comprising:
a processing chamber; and
a plasma-exposed part located within the processing chamber, the plasma-exposed part comprising an etch-resistant material that has a lower etch rate than silicon or silicon carbide when exposed to plasma process gas chemistries comprising fluorine and/or oxygen, the etch-resistant material comprising one or more of (a) an oxide, a nitride, or an oxynitride of one or more of titanium, hafnium, zirconium, or tin, or (b) one or more of silicon or silicon carbide doped with one or more of titanium, hafnium, zirconium, or tin.

8. The tool of claim 7, wherein the tool comprises a dielectric plasma etching tool.

9. The tool of claim 7, wherein the etch-resistant material is configured to form a fluoride upon reacting with the plasma process gas chemistries comprising fluorine, the fluoride has a boiling point of 1000 °C or lower.

10. The tool of claim 7, wherein the plasma-exposed part comprises an outer layer supported by a bulk portion, the outer layer comprising the etch-resistant material.

11. The tool of claim 10, wherein the bulk portion comprises one or more of silicon, silicon carbide, or silicon oxide.

12. The tool of claim 7, wherein a bulk portion and a surface of the plasma-exposed part are formed from the etch-resistant material.

13. The tool of claim 7, wherein the plasma-exposed part is an electrode, a plasma containment shroud, or an edge ring.

14. A plasma-exposed part for a plasma processing tool, the plasma-exposed part comprising:
a bulk portion; and
an outer layer supported by the bulk portion, the outer layer comprising an etch-resistant material that is different than a material of the bulk portion, the etch-resistant material configured to etch at a lower rate in a selected plasma chemistry than silicon or silicon carbide.

15. The part of claim 14, wherein the outer layer contacts the bulk portion.

16. The part of claim 14, wherein the etch-resistant material comprises one or more of an oxide, a nitride, or an oxynitride of one or more of titanium, hafnium, zirconium, or tin.

17. (canceled)

18. The part of claim 14, wherein the etch-resistant material comprises one or more of silicon or silicon carbide doped with one or more of titanium, hafnium, zirconium, or tin.

19. The part of claim 14, wherein the etch-resistant material is configured to form a fluoride upon reacting with plasma process gas chemistries comprising fluorine, the fluoride has a boiling point of 1000 °C or lower.

20. The part of claim 14, wherein the bulk portion comprises one or more of silicon, silicon carbide, or silicon oxide.

21. The part of claim 14, wherein the plasma-exposed part is an electrode, a plasma containment shroud, or an edge ring.
